(19) United States
(12) Patent Application Publication
(10) Pub. No.: US 2013/0010984 A1
(43) Pub. Date: Jan. 10, 2013

(54) Method for controlling entertainment equipment based on performer position

(76) Inventor: Thomas Hejnicki, Gross Ile, MI (US)

(21) Appl. No.: 13/179,499

(22) Filed: Jul. 9, 2011

(51) Int. Cl. H03G 3/00; G06K 7/01

(52) U.S. Cl. 381/107; 340/10.1

(57) ABSTRACT

A method and system for automatically and reliably controlling equipment for outputting sound and, potentially, lighting, pyrotechnics and other effects in live entertainment productions based upon the real-time physical location of one or more specific performers within a performance area in either an absolute sense or relative to a controlled article of equipment. The system includes a radio frequency identification subsystem and an equipment control subsystem.

The hardware composition of an audio system for delivering live musical content in a concert environment usually depends on a host of factors including, but not limited to: venue size and configuration, stage or performance area size and configuration; the number of on-stage performers, the number and types of musical instruments used, the number and placement of microphones within the performance area, speaker placement and orientation, and the types of special effects to be produced during the performance, For example, while a solo artist performing in a home or small commercial venue might require a sound production system made up of no more than one microphone, an amplifier and a loudspeaker, a multi-person band performing in a large auditorium or stadium will invariably require considerably more sound equipment. In fact, modem audio systems for producing live music in larger concert venues are typically made up of dual systems: (a) a main system for projecting a mixture of the entire band's vocal and instrumental sounds, or a “house mix,” toward the audience; and (b) a stage monitor system for projecting toward on-stage performers more isolated sound mixtures, or “monitor mixes,” so that they may hear themselves over any crowd noise and without distortion or delay. Without a stage monitor system in place, a vocalist performing in a loud arena might be unable to hear his own vocals until the amplified sound waves transmitted by speakers directed at the audience have reflected off of a distant arena wall and traveled back to the stage—potentially causing the vocalist to sing out of tune with the instrumental sound.

Both the main and monitor systems are fundamentally formed of microphones (share by both systems), amplifiers, loudspeakers and at least one mixing device for combining, modifying and routing, to the appropriate loudspeakers, the audio signals which are transmitted by the microphones, As instrument count, performer count or venue size increases, the hardware requirements and elaborateness of these sound systems tend to increase as well. Also, in addition to the hardware needed to produce sound, a concert program may include lighting, pyrotechnics and other non-audio effects that require yet other equipment to be utilized.

Typically, there is a direct correlation between the level of complexity of a live concert program and the number of non-performing personnel (i.e., sound engineers and/or stage technicians) practically needed in order to execute it. In other words, as more audio, lighting and other program effects are incorporated, more individuals are needed to manage various technical functions in accordance with a preconceived plan. In fact, in large conceit environments, there are often several considerations related to live sound mixing, alone, that can necessitate involvement of multiple sound engineers.

In the area of sound mixing, there usually is a first need to produce both house and monitor mixes. In a solo performance/small stage environment, this means creating a single monitor mix to be projected toward the performer by as few as one monitor speaker, as well as a house mix that is projected at the audience by a small number of main speakers. Generally, a lone engineer can create those two sound mixes. However, in larger concert environments with multiple performers involved, not only must separate house and stage monitor mixes be created, but it might be desirable to periodically modify the house mix in accordance with a designed audio program. For example, it may be necessary to amplify vocal or instrumental sound generated by some performers and/or attenuate that generated by others in order that the main speakers output an audio mix according to a particular program.

It is also sometimes desirable to create distinctly different stage mixes for each performer so that each one hears a mix in which their individually produced sound is more amplified than or is isolated from that of other performers. Furthermore, if performers are to freely move throughout the stage area using wireless microphones, it may also be preferable to dynamically route each custom monitor mix to monitor speakers at different stage positions according to the real time locations of those moving performers, thereby enabling them to continuously hear their individual monitor mixes. Also, if performers are moving around with live microphones, a sound engineer may need to momentarily mute a microphone, in order to avoid generating feedback noise, when it is brought within close proximity and facing orientation to a main speaker. Consequently, in a large concert environment, more than one person may be needed to constantly observe the stage and to execute the various sound engineering tasks involved in creating distinct audio mixes and making audio signal routing and level adjustments on-the-fly.

This, of course, increases the cost of and potential for human error in the live sound production process.

In addition to creating and properly routing the sound mixes, an engineer may be responsible for ensuring that various forms of noise are filtered from the mixes as well. For one, audience noise should be excluded, Secondly, bleed, or a microphone's pickup of performance sound not intended for that particular microphone, should be minimized. Because sound waves produced by one source travels different distances to reach different microphone positions, if the same sound is detected by multiple microphones, similar audio signals transmitted by those microphones may arrive at a mixing device at different times to create a comb filtering effect which may be undesirable. As the microphone count increases, the potential gain before feedback occurs is reduced—limiting amplification of the microphones—and the potential for bleed is increased. Therefore, microphones should be muted whenever they are not intended to be in use.

However, the proposition of having a sound engineer manually mute or fade different microphones on-the-fly in attempt to both filter out unwanted sound and maximize acoustical bandwidth can be overly tedious and problematic. For one, performers may provide spontaneous utterances or artistic improvisations meant for audience consumption, but that were not expected to be in the audio program. Yet, since an engineer cannot always anticipate the occurrence and timing of such things, some audio of that nature may be lost simply due to it being generated at moments when certain microphones happen to be muted or faded out. Consequently, mechanisms that do not require human anticipation and, instead, are capable of distinguishing unwanted from wanted sound and then filtering out the unwanted sound can be valuable tools in live music production.

One well-known such mechanism is the noise gate which is an electronic device used to block audio signals that are below a user-selected threshold level from being amplified and outputted as sound by loudspeakers. On the positive side, a noise gate can prevent loudspeakers from outputting crowd noise that is captured by a performer's microphone, but at a significantly lower decibel level than is the performer's voice. However, on the negative side, it can also have the effect of chopping off the end of a performer's vocals as they trail off and drop below the pre-set gate threshold—especially if that threshold must he set relatively high due to there being loud crowd noise. Therefore, even though it relieves some human burden, the noise gate is not always an ideal tool for use in live performances.

Furthermore, because the noise gate does not distinguish sources of vocal or instrumental sound, it is ineffective in preventing a sound system from blocking or otherwise muting sound based on its specific source, rather than on its level. Therefore, in a conceit program in which a performers dedicated microphone is stationary and that performer will momentarily vacate it, any means for automatically muting that microphone when vacated must identify the relative spacing of performer and microphone and then control microphone functionality accordingly. In fact, a mechanism which operates according to such spacing logic is disclosed in U.S. Pat. No. 5,818,949 to Deremer, et al. More specifically, Deremer discloses a microphone that uses an infrared emitter and detector and a comparator to determine whether the microphone is receiving an infrared reflection from another object, such as a human body, that is close enough to warrant enabling the microphone to output audio signaling.

Still, while infrared technology is effective for identifying the proximity of a human body and can be used for the purpose of enabling and disabling a microphone according to that proximity, like the noise gate, it is incapable of distinguishing different human bodies from one another. Consequently, infrared technology could not facilitate, for example, a concert program in which a microphone is supposed to function only when a specific individual performer is holding or standing right before it (as opposed to another person holding it or being in proximity). In addition, since incandescent light sources produce infrared radiation, concert lighting effects may provide false indications to the sensors of an infrared-based microphone control system and cause controlled microphones to function (or not) at inappropriate times.

It can, therefore, be appreciated that there exists a need for an entertainment control system that automatically enables or disables a microphone based upon the distance between it and a specific individual performer and that is less susceptible to false triggers than are microphone muting systems of the prior art. It can be further appreciated that there is a need for such a position responsive system to be capable of controlling other audio-related functions, such as being able to selectively amplify or attenuate audio signals or dynamically route audio signals to different loudspeakers according to a performer's physical location within a stage area. Moreover, it can be appreciated that there is a need for such a system to be adapted to also control non-audio aspects of a live conceit program, such as lighting and pyrotechnics, according to similar location considerations. The present inventors submit that the entertainment control system of the present invention substantially fulfills all of these needs.

### SUMMARY OF THE INVENTION

The present invention generally relates to automated controls for live entertainment production, and it is specifically directed to a method and system for automatically and reliably controlling equipment for outputting sound and, potentially, lighting, pyrotechnics and other effects in live entertainment productions based upon the real-time physical location of one or more specific performers within a performance area in either an absolute or relative sense.

In its broadest sense, the invention is a combination radio frequency identification (“RFID”) and entertainment equipment control system that both: (a) determines either (i) relative spacing between a particular individual and a particular transducer, power-adjuster or other outputting device (e.g., a microphone, speaker, light source, amplifier, attenuator, etc) or (ii) the location of an individual within an RFID-mapped stage area; and (b) controls the operation or treatment of the output of the device based upon that relative spacing or location determination. Its inventors anticipate that the present system will be used, primarily, to mute a stationary microphone—by either disabling the microphone itself or by attenuating its output signal—when the specific performer to whom the stationary microphone is assigned has moved beyond a threshold distance from it, They also anticipate the system will be used to similarly mute a mobile microphone when it is transported out of or into a particular area of the performance stage. And in addition to audio control applications, they anticipate that the system will be used to control operability of light sources and pyrotechnic initiators based upon the same determinations of specific performer location or relative spacing.

It is, therefore, an object of the present invention to determine whether, in the context of multiple people being within a small performance area, one specific such individual is within a predefined distance of a particular microphone or other outputting device. In one aspect of the invention, an RFID reader is attached to the outputting device and uniquely coded RFID tags are worn by each of multiple on-stage performers. So, when a tag-wearing performer is positioned within the reading zone of a reader, the reader specifically recognizes both his presence and his specific identity by its reading of data stored on his RFID tag.

It is another object of the invention to provide real-time monitoring of the location of one or more microphone-carrying performers within a performance area. In another aspect of the invention, multiple RFID readers are strategically mapped throughout a performance area, and unique RFID tags are both worn by each of multiple performers and attached to each microphone. So, as performer brings his microphone to within the reading zone of a reader, the reader recognizes that presence by its reading of unique identifying data stored on the tags worn by him and attached to his held or worn microphone.

It is another object of the invention to control the operation of an outputting device based on these spacing and location recognitions. In another aspect of the invention, the RFID readers are all connected to a computer which is programmed to control at least one outputting device (e.g., microphone, loudspeaker, amplifier, attenuator, light emitter, pyrotechnic initiator) based upon the positioning a particular RFID tag within the mapped area or relative to a particular RFID reader. For example, where an RFID reader is attached to a stationary microphone (“mic-1”) and an RFID tag is worn by a vocalist, the computer may be programmed to mute mic-1 so long as the vocalist's worn tag is not close enough to mic-1 be read by its attached reader. For another example, where an RFID reader is attached to a main loudspeaker (“speaker-1”), a first RFID tag is attached to a mobile microphone (“mic-2”), and a second tag is worn by a vocalist (e.g., tucked inside a garment pocket or attached to a lanyard) the computer may be programmed to mute disable speaker-1 so long as both tags are close enough to it to be read by the attached reader.

It is another object of the present invention to control treatment of the output of an outputting device (e.g., routing, power level, etc.). For example, the computer may be programmed to attenuate—even completely—the sound signal output of the aforementioned mic-2 before that signal is routed to speaker-1, Similarly, microphone signal output can be amplified to a predetermined level based on an RFID tag proximity determination.

It is yet another object of the present invention to control the operation of light banks, lasers, fireworks and other show effects based upon similar RFID proximity determinations.

### BRIEF DESCRIPTION OF THE DRAWINGS

FIG. 1 is a diagrammatic illustration of a system for controlling a microphone based on relative location of the microphone and its dedicated user according to an embodiment of the invention;

FIG. 2 is a diagrammatic illustration of a system for controlling a microphone based on the location of the microphone and its dedicated user according to another embodiment of the invention;

FIG. 3 is a flowchart of a method for controlling a microphone according to an embodiment of the invention; and

FIG. 4 is a flowchart of a method for controlling a microphone according to another embodiment of the invention

### DETAILED DESCRIPTION OF THE PREFERRED EMBODIMENTS

This disclosure, as defined by the claims that follow and as presented by way of example in the accompanying drawings, relates to an RFID-based entertainment equipment control system and method for it use. The present inventors anticipate that this system will be used in controlling the operability or output of a variety of transducers, power adjusters and other outputting devices, including loudspeakers, amplifiers, attenuators, light emitters, pyrotechnic launchers and conceivably other apparatuses commonly used in live entertainment productions. So, although the following discussion will primarily focus on microphones (or their audio signal output) as being the particular devices controlled according to location or distance determinations made with RFID technology, one should remain aware that the functionality and/or output of other types of entertainment equipment could be controlled according to similar logic and in similar fashion.

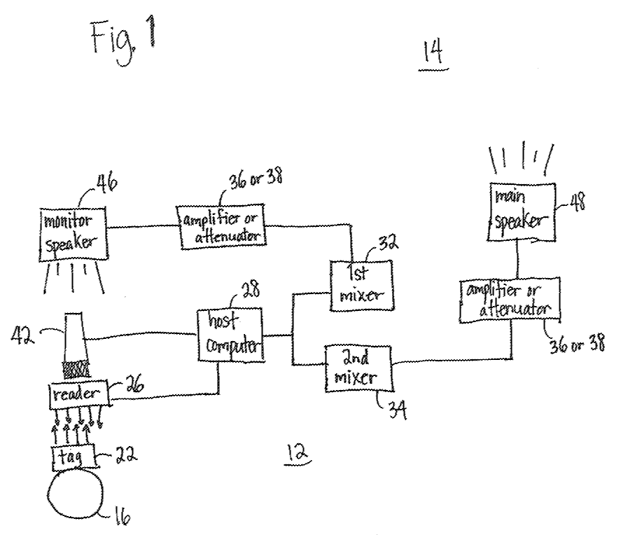

The present entertainment control system, in fact, comprises two apparatus subsystems: (1) an entertainment equipment subsystem and (2) an RFID subsystem. In preferred embodiments, the entertainment equipment subsystem is, more specifically, a sound system having most, of not all, of its hardware set within a performance area 12 (e.g., on an arena stage) and configured to project sound at both the performance area 12 and an audience area 14. At its most basic level, the sound subsystem comprises a microphone connected to loudspeaker. However, in a first preferred embodiment schematically depicted in FIG. 1, it comprises multiple microphones 42 that are connected to a set of monitor loudspeakers 46 via both a first sound mixing device 32 and amplifiers 36 and that are connected to a set of main loudspeakers 48 via both a second sound mixing device 34 and more amplifiers 36.

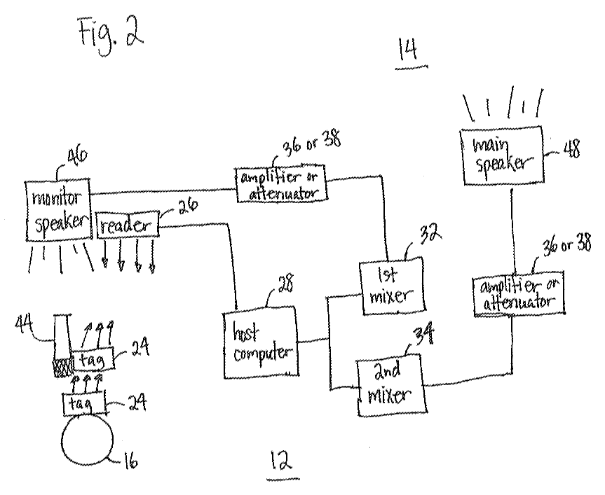

One microphone 42 is assigned to each human performer 16. These microphones 42 are stand-mounted and expected to remain stationery, even though their assigned performers 16 might move throughout the stage area 12 and momentarily vacate them at points during the musical performance. By hardwire or wirelessly, each microphone 42 is communicatively connected to both mixing devices 32, 34 such that when sound waves generated by a performer 16 is captured by a microphone 42, it is converted to audio signals which are transmitted to both mixing devices 32, 34. The mixing devices 32, 34 may be analog or digital, manually-operated consoles or automated devices, or any combination thereof. In fact, they may actually be software logic stored on the same or separate computing hardware. However, in the two sound subsystem examples embodied in FIGS. 1 and 2, both mixers 32, 34 are digital automated devices—the first mixer 32 being wired to monitor loudspeakers 46, and the second 34 to main loudspeakers. Amplifier 36 may be positioned between the mixing devices 32, 34 and their respective loudspeakers 46, 48, although, they would not be needed for use with powered main speakers 48. Each monitor speaker 46 sits fairly close to and is facing a microphone position so that a performer 16 standing before a microphone 42 hears a monitor mix. The main speakers 48 are arranged to direct a house mix toward the audience area 14.

The RFID subsystem is of a type well-known in the art and includes tags 22, readers 26 and a host computer 28. However, it should be noted that this “computer” 28 could actually be software logic stored on the same hardware previously introduced as the first sound mixer 32 or second sound mixer 34 which feeds audio signaling to the monitor speakers 46 and main speakers 48, respectively. Also, the readers 26 may be configured to directly activate switch mechanisms found in certain entertainment production equipment, thereby rendering a separate computing device 28 unnecessary to the control process.

Each RFID tag 22 contains a microchip (not shown) on which unique identifying data D is stored, as well as an antenna (not shown) for receiving and transmitting a radio frequency signal from/to a reader 26. In this first embodiment of the control system, the RFID tags 22 are of the unpowered, or “passive,” variety. The readers 26 are essentially antennas that transmit radio waves for defined distances, creating electromagnetic reading zones around them. So, while a passive tag 22 is within a certain distance of a reader 26, the tag 22 is powered by reading zone energy, and the identifying data D encoded in its microchip can be read the reader 26. The reader 26 then transmits that data D to the host computer 28 for appropriate processing.

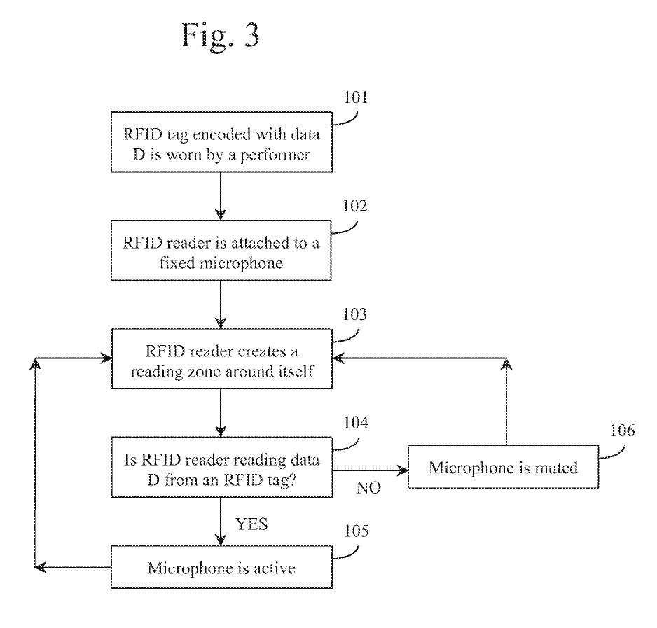

In this first embodiment of the control system, the passive RFID and audio subsystems are configured to determine whether an individual stage performer 16 is proximate its specifically assigned microphone 42 and to then use that proximity determination in controlling the operation or sound signal output of the assigned microphone 42 according to the predefined logic rules of a performance program, FIG. 3 displays the basic steps of what the present inventors anticipate being a popular such program that is characterized by a microphone 42 remaining disabled from transmitting sound signals whenever the individual performer 16 to which it is specifically assigned is not standing very close to it. To effectively execute this particular program logic, an RFID tag 22 encoded with identifying data D that associates the tag 22 with a particular microphone 42 should be worn by a performer 16 (step 101). Additionally, an RFID reader 26 should be attached to the stationary microphone 42 or its stand (or placed very close thereto; step 102).

So that its sound signaling capacity is disableable by non-manual means, the microphone 42 may possess a muting circuit (not shown) of some type known in the art that does not require manual manipulation and, instead, is signal-activated. For example, the microphone muting circuit can be a relay that remains energized and closed - making the microphone 42 active and unmuted—while it continuously receives from the computer 28 or RFID reader 26 an electrical signal indicating that the reader 26 detects, within its reading zone, an RFID tag 22 containing the associating data D (steps 104 & 105). Conversely, when that same worn tag 22 is outside the detection range (i.e., the performer 16 has ventured away from his assigned microphone 42), the relay circuit remains open and the microphone 42 is disabled (steps 104 & 106). Of course, a reader 26 used should be selected based on the length of its tag reading range. So, for this application, it would be desirable to use a relatively low-powered reader 26 that creates a short-reaching electromagnetic field capable of powering and reading only a passive tag 22 located not more than a few feet (or several inches) away.

It is not essential that the microphone 42 have a muting circuit that can be controlled by the RFID subsystem or that it is otherwise directly disableable, however. In fact, the just described program logic could be followed to effectively mute the microphone 42 by way of manipulating its audio signal chain(s). For example, the host computer 28 in communication with the reader 26 when it is not communicating with the associated RFID tag 22 can be configured to notify the first sound mixer 32 to attenuate or simply not transmit to a corresponding monitor speaker 46 any sound signal output of the microphone 42 associated with the undetected tag 22. Furthermore, rather than controlling the functionality or signal output of the microphone 42, the computer 28 may be programmed to control operation of a noise gate (not shown) or amplifier 36 in a way that produces essentially the same muting effect. For example, the computer 28 can be programmed to raise the threshold level of a noise gate extremely high during periods in which the performer-worn RFID tag 22 is not proximate its associated microphone 42 (as indicated by the RFID reader 26 attached to the microphone 42 not detecting an RFID tag 22 bearing data D). This would cause any audio signals transmitted by the microphone 42 to be blocked from traveling to a system amplifier 36 and monitor speaker 46 during those periods. Conversely, the amplifier 36 or an attenuating device (not shown) situated within the sound subsystem's audio signal path can be selectively manipulated to raise or lower the power of audio signals transmitted by a microphone 42 according to RFID subsystem determinations regarding whether an associated human performer 16 (“associated” by virtue of having on its person an RFID tag 22 containing data D) is proximate its microphone 42.

In FIG. 2 is depicted a second embodiment of the entertainment control system—one that includes a sound subsystem configured similar to that of the above described first embodiment, except that its microphones 44 are mobile and are anticipated to travel throughout the performance area 12 with their respective assigned performers 16 during a concert program. The RFID subsystem of this second embodiment preferably utilizes battery-powered, “active” RFID tags 24, instead of passive ones. As is the case in the control system first embodiment, each performer 16 is to wear one of the uniquely coded tags 24, However, a tag 24, rather than a reader 26, is also attached to each mobile microphone 44. Finally, the readers 26 are spatially mapped to create separate RFID reading zones throughout the performance area 12, rather than being attached or necessarily remaining close to the microphones 44.

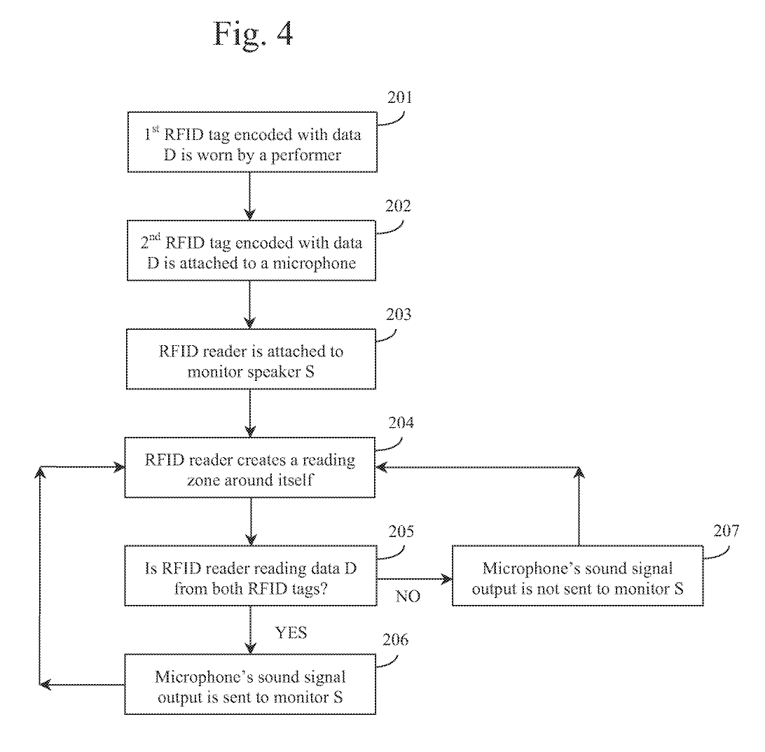

The present inventors anticipate that this embodiment of the control system will be used to facilitate a variety of audio control logics. As an example that is displayed in FIG. 4, it could be used to dynamically route multiple vocalists' monitor mixes from speaker-to-speaker as they move about the performance area 12 exchanging positions before different monitor speakers 46. To wit, a first RFID tag 22 encoded with identifying data D should be worn by a performer 16 (step 201), and a second RFID tag 22 encoded with the same identifying data D is attached to the performer's assigned mobile microphone 42 (step 202). Additionally, an RFID reader 26 should be attached to a monitor speaker 46 or placed very close thereto (step 203). Then, the host computer 28, in communication with the reader 26, can notify the first sound mixer 32 to route the sound signals transmitted by the microphone 32 to that monitor speaker 46 when the reader 26 is able to simultaneously read both RFID tags 22 containing data D (steps 205 & 206) and to not route them to that monitor 46 when it is unable to simultaneously detect them within its reading zone (steps 205 & 207).

As another example, it could be used to mute a mobile microphone 44, in any manner previously described, when both that microphone 44 and its assigned vocalist 16 get close enough to a main speaker 48 to cause noisy audio feedback emissions (on the theory that the vocalist 16 is probably facing the audience area 14 and his held microphone 44 is likely pointing in the direction of the nearby speaker 48).

This and similar embodiments of the present control system could also be employed to control lights, pyrotechnic launchers and other outputting devices based upon the presence of one or more performers 16 and their respective dedicated microphones 44 within certain portions of performance area 12. For example, a fixed spotlight (not shown) could be activated only when a specific performer 16 walks within its shine path (where an RFID reader 26 has been positioned). Moreover, RFID technology specifically enable those automatic equipment activations to be limited to instances in which performers occupy areas while actually performing (e.g., while singing), as opposed to other moments in which they may happen to be there without their microphones 44 and are not performing.

It is understood that substitutions and equivalents for and combinations of various elements set forth above may be obvious to those skilled in the art and may not represent a departure from the spirit of the invention. Therefore, the full scope and definition of the present invention is to be set forth by the claims that follow.

What is claimed is:

1. An entertainment control system for use in a performance area, the system comprising:
a transducer;
a radio frequency identification (RFID) tag for attaching to a performer, wherein the tag contains data associating it with the transducer;
an RFID reader that reads the associating data when the tag is within a reading distance of the reader; and
a computer in communication with the reader, wherein the computer determines whether the tag is within a reading distance of the reader, as indicated by whether the reader is reading the associating data, and controls operation of the transducer based on that determination.

2. The system of claim 1, further comprising a switch for enabling operation of said transducer, wherein said computer sends to the switch an enabling signal when said tag is within the reading distance of said reader.

3. The system of claim 1, wherein said transducer is a microphone.

4. The system of claim 3, wherein said computer enables said microphone to output sound signals when said tag is within the reading distance of said reader and disables said microphone when said tag is not, or vice versa.

5. The system of claim 3, wherein said computer allows sound signals outputted by said microphone to be converted to audible sound when said tag is within the reading distance of said reader and does not allow sound signals outputted by said microphone to be converted to audible sound when said tag is not, or vice versa.

6. The system of claim 3, further comprising:
a monitor loudspeaker for outputting audible sound towards the performance area, wherein the monitor loudspeaker receives sound signals outputted by said microphone only when said tag is within the reading distance of said reader; and
a main loudspeaker for outputting audible sound towards an audience area, wherein the main loudspeaker receives sound signals outputted by said microphone regardless of whether said tag is within the reading distance of said reader.

7. The system of claim 1, wherein said transducer is a loudspeaker, wherein said computer enables the loudspeaker to output audible sound when said tag is within the reading distance of said reader and disables the loudspeaker when said tag is not, or vice versa.

8. The system of claim 1, wherein said transducer is a means for emitting light, wherein said computer enables the light emitting means to emit light when said tag is within the reading distance of said reader and disables the light emitting means when said tag is not, or vice versa.

9. An entertainment control system for use in a performance area, the system comprising:
a power-adjusting device;
a radio frequency identification (RFID) tag for attaching to a performer, wherein the tag contains data associating it with the power-adjusting device;
an RFID reader that reads the associating data when the tag is within a reading distance of the reader; and
a computer in communication with the reader, wherein the computer determines whether the tag is within a reading distance of the reader, as indicated by whether the reader is reading the associating data, and controls operation of the power-adjusting device based on that determination.

10. The system of claim 9, further comprising a switch for enabling operation of said power-adjusting device, wherein said computer sends to the switch an enabling signal when said tag is within the reading distance of said reader.

11. The system of claim 9, wherein said power adjusting device is an amplifier, wherein said computer enables the amplifier to amplify sound signals when said tag is within the reading distance of said reader and disables the amplifier when said tag is not, or vice versa.

12. The system of claim 9, wherein said power adjusting device is an attenuator, wherein said computer enables the attenuator to attenuate sound signals when said tag is within the reading distance of said reader and disables the attenuator when said tag is not, or vice versa.

13. A method of controlling an entertainment system used in a performance area, the method comprising:
attaching, to a performer, a radio frequency identification (RFID) tag that contains data associating it with an outputting device;
placing, within the performance area, an RFID reader that reads the associating data when the tag is within a reading distance of the reader;
determining whether the tag is within a reading distance of the reader as indicated by whether the reader is reading the associating data; and
controlling an outputting device or its output based on that determination.

14. The method of claim 13, wherein controlling comprises at least one of:
(a) enabling said outputting device to output sound when said tag is within the reading distance of said reader and disabling said outputting device from outputting sound when said tag is not, or vice versa;
(b) enabling said outputting device to output sound signals when said tag is within the reading distance of said reader and disabling said outputting device from outputting sound signals when said tag is not, or vice versa;
(c) routing, to a particular loudspeaker, sound signals outputted by said outputting device when said tag is within the reading distance of said reader and not routing those sound signals to that loudspeaker when said tag is not;
(d) enabling said outputting device to emit light when said tag is within the reading distance of said reader and disabling said outputting device from emitting light when said is not, or vice versa; and
(e) enabling said outputting device to output pyrotechnic articles when said tag is within the reading distance of said reader and disabling said outputting device from outputting pyrotechnic articles when said tag is not, or vice versa;
(f) enabling said outputting device to amplify sound signals when said tag is within the reading distance of said reader and disabling said outputting device from amplifying sound signals when said tag is not, or vice versa; and
(g) enabling said outputting device to attenuate sound signals when said tag is within the reading distance of said reader and disabling said outputting device from attenuating sound signals when said tag is not, or vice versa.

15. The method of claim 13, further comprising:
attaching, to the outputting device, a second RFID tag that contains said associating data;
determining whether the 1^{st} and 2^{nd} tags are simultaneously within the reading distance of the reader as indicated by whether the reader is reading the associating data from both tags; and
controlling the outputting device or its output based on that determination.

16. The method of claim 15, wherein controlling comprises at least one of:
(a) enabling said outputting device to output sound when said tags are simultaneously within the reading distance of said reader and disabling said outputting device from outputting sound when said tags are not simultaneously within the reading distance of said reader, or vice versa;
(b) enabling said outputting device to output sound signals when said tags are simultaneously within the reading distance of said reader and disabling said outputting device from outputting sound signals when said tags are not simultaneously within the reading distance of said reader, or vice versa;
(c) routing; to a particular loudspeaker, sound signals outputted by said outputting device when said tags are simultaneously within the reading distance of said reader and not routing those sound signals to that loudspeaker when said tags are not simultaneously within the reading distance of said reader;
(d) enabling said outputting device to emit light when said tags are simultaneously within the reading distance of said reader and disabling said outputting device from emitting light when said tags are not simultaneously within the reading distance of said reader, or vice versa; and
(e) enabling said outputting device to output pyrotechnic articles when said tags are simultaneously within the reading distance of said reader and disabling said outputting device from outputting pyrotechnic articles when said tags are not simultaneously within the reading distance of said reader, or vice versa;
(f) enabling said outputting device to amplify sound signals when said tags are simultaneously within the reading distance of said reader and disabling said outputting device from amplifying sound signals when said tags are not simultaneously within the reading distance of said reader, or vice versa; and
(g) enabling said outputting device to attenuate sound signals when said tags are simultaneously within the reading distance of said reader and disabling said outputting device from attenuating sound signals when said tags are not simultaneously within the reading distance of said reader, or vice versa.
